(19) United States
(12) Patent Application Publication
(10) Pub. No.: US 2024/0276776 A1
(43) Pub. Date: Aug. 15, 2024

(54) Display Substrate and Display Device

(71) Applicants: Hefei BOE Joint Technology Co.,Ltd., Hefei, Anhui (CN); BOE Technology Group Co., Ltd., Beijing (CN)

(72) Inventor: Wenbin JIA, Beijing (CN)

(21) Appl. No.: 18/023,382

(22) PCT Filed: May 26, 2022
(86) PCT No.: PCT/CN2022/095285

§ 371 Date: Feb. 27, 2023

(51) Int. Cl. H10K 59/122; H10K 59/121

(52) U.S. Cl. CPC H10K 59/122; H10K 59/121

(57) ABSTRACT

A display substrate includes a display area including multiple first electrodes and a pixel definition layer; the pixel definition layer includes multiple blocking portions extending in a second direction and spaced in a first direction, and multiple groups of spacing portions spaced in the second direction, each group of spacing portions includes multiple spacing portions spaced in the first direction, each spacing portion is between two adjacent blocking portions; a portion of a blocking portion between two adjacent spacing portions in the first direction is a first portion, and a portion of the blocking portion between two adjacent first portions is a second portion; in the display area, the first portion includes a first material layer and a second material layer that are sequentially stacked in a direction away from the base substrate, a material of the second material layer is the same as a material of the second portions.

### CROSS-REFERENCE TO RELATED APPLICATION

The present application is a U.S. National Phase Entry of International Application PCT/CN2022/095285 having an international filing date of May 26, 2022, and entitled “Display Substrate and Display Device”, the contents of the above-identified application should be construed as being hereby incorporated by reference in its entirety.

### TECHNICAL FIELD

Embodiments of the present disclosure relate to, but are not limited to, the field of display technologies, and more particularly to a display substrate and a display device

### BACKGROUND

In an organic light emitting diode (OLED) display substrate, organic film layers of OLED devices are mainly formed by an evaporation process and a solution process. At present, evaporation process technology has been applied in mass production, but there are some problems with this technology, such as low material utilization rate and high production cost. Film formation methods of solution process mainly include ink-jet printing, spin coating, screen printing and so on.

The ink-jet printing process requires that a pixel definition layer (PDL) is manufactured in advance on a substrate on which electrodes are formed to limit precise flow of ink droplets into pixel openings of specified sub-pixels. Some display substrates have a design of pixel pits, and uniformity of film formation in pixel pits decreases with an increase of resolution of a display substrate (pixel openings become smaller), thus affecting a service life and quality of products. In addition, because of a limitation from printer nozzle hardware, stability of each nozzle cannot guarantee a consistent volume of ink droplets sprayed into each pixel pit. Although a hybrid algorithm is used for printing, it is still impossible to avoid a problem of different brightness along a printing direction (Suji Mura) when the display substrate is lit, and the higher the resolution, the more serious the Suji Mura problem is.

For this reason, a Line Bank structure is used in some display substrates, and the ink of each column of sub-pixels with a same color is communicated with each other, so that the ink of each sub-pixel in the same column are averaged and differences between ink volumes of the sub-pixels are reduced. At the same time, due to the influence of atmosphere, the uniformity of film formation by printing can be improved and the Suji Mura problem is reduced. In addition, the Line Bank structure reduces requirements for printer hardware's accuracy. At present, there are two commonly used line bank structures in the industry: double-layer line bank and single-layer line bank. The single-layer line bank is generally not taken into consideration because of constraints of materials. However, in a development process of the double-layer line bank structure, it is found that ink droplets are prone to overflow at an overlapping position between two layers of banks, which results in cross-color or uneven film thickness, thus forming Mura.

### SUMMARY

The following is a summary of subject matter described herein in detail. The summary is not intended to limit the protection scope of claims.

An embodiment of the present disclosure provides a display substrate, including a display area and a non-display area located at a periphery of the display area, wherein the display area includes a drive structure layer, a light emitting structure layer and an encapsulation structure layer which are sequentially stacked on the base substrate; the light emitting structure layer includes a first electrode layer, a pixel definition layer, a light emitting functional layer and a second electrode layer;
the first electrode layer includes multiple first electrodes disposed at a side of the drive structure layer away from the base substrate;
the pixel definition layer includes multiple blocking portions extending along a second direction, the multiple blocking portions are arranged at intervals in a first direction, the pixel definition layer further includes multiple groups of spacing portions, each group of spacing portions includes multiple spacing portions arranged at intervals along the first direction, each of the spacing portions is located between two adjacent blocking portions, the multiple groups of spacing portions are arranged at intervals in the second direction, wherein the first direction intersects with the second direction, the multiple blocking portions and the multiple groups of spacing portions form multiple pixel openings that expose surfaces of the first electrodes away from the base substrate;
a portion of a blocking portion located between two adjacent spacing portions in the first direction is a first portion, and a portion of the blocking portion located between two adjacent first portions in the second direction is a second portion;
in the display area, the first portion includes a first material layer and a second material layer that are sequentially stacked along a direction away from the base substrate, a material of the first material layer is the same as a material of the spacing portions, a material of the second material layer is the same as the material of the second portions, a thickness of a portion of a second material layer in the first portion that is not overlapped with the first electrodes is H1, and a thickness of a portion of a second portion that is not overlapped with the first electrodes is H2, H1=H2; alternatively, in the display area, the material of the first portions is the same as that of the second portions, and the material of the second portions is different from that of the spacing portions, a thickness of a portion of a first portion that is not overlapped with the first electrodes is H1, and a thickness of a portion of a second portion that is not overlapped with the first electrodes is H2, H1=H2; and
the light emitting functional layer is disposed on surfaces of the first electrodes away from the base substrate, and the second electrode layer is disposed at a side of the pixel definition layer and the light emitting functional layer away from the base substrate; the first electrodes, the light emitting functional layer and the second electrode layer are sequentially stacked to form light emitting devices.

Other aspects may be understood upon reading and understanding of the drawings and the detailed description.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, and not intended to form limitations on the technical solutions of the present disclosure. Shapes and sizes of components in the drawings do not reflect actual scales, and are only intended to schematically illustrate contents of the present disclosure.

FIG. 1 is a schematic diagram of a structure of a pixel arrangement of a display substrate according to some exemplary embodiments.

FIG. 2 is a schematic diagram of a cross-sectional structure taken along K-K in FIG. 1 according to some exemplary embodiments.

FIG. 3 is a schematic diagram of a planar structure of a pixel definition layer of a display substrate in some arts.

FIG. 4a is a schematic diagram of a cross-sectional structure taken along A′-A′ in FIG. 3.

FIG. 4b is a schematic diagram of a cross-sectional structure taken along B′-B′ in FIG. 3.

FIG. 4c is a schematic diagram of a cross-sectional structure taken along C′-C′ in FIG. 3.

FIG. 4d is a schematic diagram of a cross-sectional structure taken along D′-D′ in FIG. 3.

FIG. 5 is a schematic diagram of a structure in which an overflow occurs in a process of forming an organic film layer of an OLED device using an ink-jet printing process with the pixel definition layer structure of FIG. 3.

FIG. 6 is a schematic diagram of a planar structure of a display substrate according to some exemplary embodiments.

FIG. 7a is a schematic diagram of a cross-sectional structure taken along A-A in FIG. 6 according to some exemplary embodiments.

FIG. 7b is a schematic diagram of a cross-sectional structure taken along B-B in FIG. 6 according to some exemplary embodiments.

FIG. 7c is a schematic diagram of a cross-sectional structure taken along C-C in FIG. 6 according to some exemplary embodiments.

FIG. 7d is a schematic diagram of a cross-sectional structure taken along D-D in FIG. 6 according to some exemplary embodiments.

FIG. 8a is a schematic diagram of a structure after an adjustment layer is formed on a driving backplate according to some exemplary embodiments.

FIG. 8b is a schematic diagram of a structure after a first electrode is formed according to some exemplary embodiments.

FIG. 8c is a schematic diagram of a structure after a first sub-pixel definition layer is formed according to some exemplary embodiments;

FIG. 9 is a schematic diagram of a planar structure of a display substrate according to some other exemplary embodiments.

FIG. 10 is a schematic diagram of a cross-sectional structure taken along E-E in FIG. 9 according to some exemplary embodiments.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

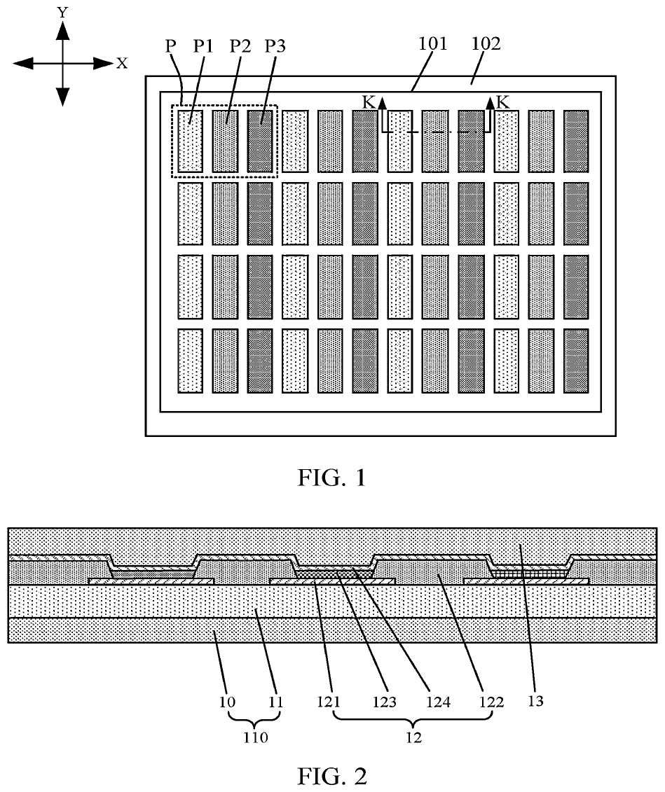

As shown in FIG. 1, FIG. 1 is a schematic diagram of a structure of a pixel arrangement of a display substrate according to some exemplary embodiments, the display substrate includes a display area 101 and a non-display area 102 located at a periphery of the display area 101. The display area 101 includes multiple pixel units P arranged in an array on a base substrate, and each pixel unit P includes multiple sub-pixels sequentially arranged along a first direction (X direction, which may be referred to as a row direction). Sub-pixels of a same column in a second direction (Y direction, which may be referred to as a column direction) emit light of a same color, and the first direction intersects with the second direction. Exemplarily, each pixel unit P may include three sub-pixels arranged side by side along the first direction, which are respectively a first sub-pixel P1 emitting a first color light (e.g. red light), a second sub-pixel P2 emitting a second color light (e.g. green light) and a third sub-pixel P3 emitting a third color light (e.g. blue light). Multiple pixel units P are sequentially arranged in the first direction (direction X), and multiple sub-pixels located in the same column in the second direction (direction Y) can emit light of a same color. Exemplarily, the first direction and the second direction may intersect perpendicularly. An area represented by each sub-pixel in FIG. 1 is a light emitting area or a pixel opening area of each sub-pixel. The arrangement of pixels of the display substrate and the types and numbers of sub-pixels contained in each pixel unit are not limited in embodiments of the present disclosure.

As shown in FIG. 2, FIG. 2 is a schematic diagram of a cross-sectional structure taken along K-K of FIG. 1 according to some exemplary embodiments. The display area includes a drive structure layer 11, a light emitting structure layer 12 and an encapsulation structure layer 13 sequentially stacked on a base substrate 10. The light emitting structure layer 12 includes a first electrode layer, a pixel definition layer 122, a light emitting functional layer 123 and a second electrode layer 124. An integrated structure of the base substrate 10 and the drive structure layer 11 disposed on the base substrate 10 may be referred to as a driving backplate 110.

The drive structure layer 11 may include multiple pixel driving circuits. Each pixel driving circuit may include multiple thin film transistors (T) and a storage capacitor (C), and the pixel driving circuit may have a structure of 3TIC, 4TIC, 5TIC, 5T2C, 6TIC or 7TIC or the like, which is not limited in the embodiment of the present disclosure. The drive structure layer 11 further includes multiple data lines and multiple gate lines, as well as other signal lines.

The first electrode layer includes multiple first electrodes 121 disposed at a side of the drive structure layer 11 away from the base substrate 10. Each of the first electrodes 121 is connected to one of the pixel driving circuits. The pixel definition layer 32 is disposed at a side of the multiple first electrodes 121 away from the base substrate 10 and is provided with multiple pixel openings. Each pixel opening exposes a surface of one corresponding first electrode 121 away from the base substrate 10. The light emitting functional layer 123 may be disposed within the pixel opening, the light emitting functional layer 123 may include an organic light emitting layer (i.e., a light emitting material layer), and the light emitting functional layer 123 may include any one or more film layers of a hole injection layer, a hole transport layer, an electron transport layer, and an electron injection layer. At least one film layer of the light emitting functional layer 123 can be manufactured by an ink-jet printing process. The second electrode layer 124 is disposed at a side of the pixel definition layer and the light emitting functional layer 123 away from the base substrate 10. The first electrode 121, the light emitting functional layer 123 and the second electrode layer 124 are stacked sequentially to form a light emitting device, and the light emitting device may be an OLED device. Each sub-pixel includes a light emitting device and a pixel driving circuit configured to drive the corresponding light emitting device to emit light.

The encapsulation structure layer 13 may include multiple inorganic material layers that are stacked, or may include a first inorganic material layer, an organic material layer, and a second inorganic material layer stacked sequentially. The materials of the first inorganic material layer and the second inorganic material layer may include any one or more of silicon nitride, silicon oxide, and silicon oxynitride.

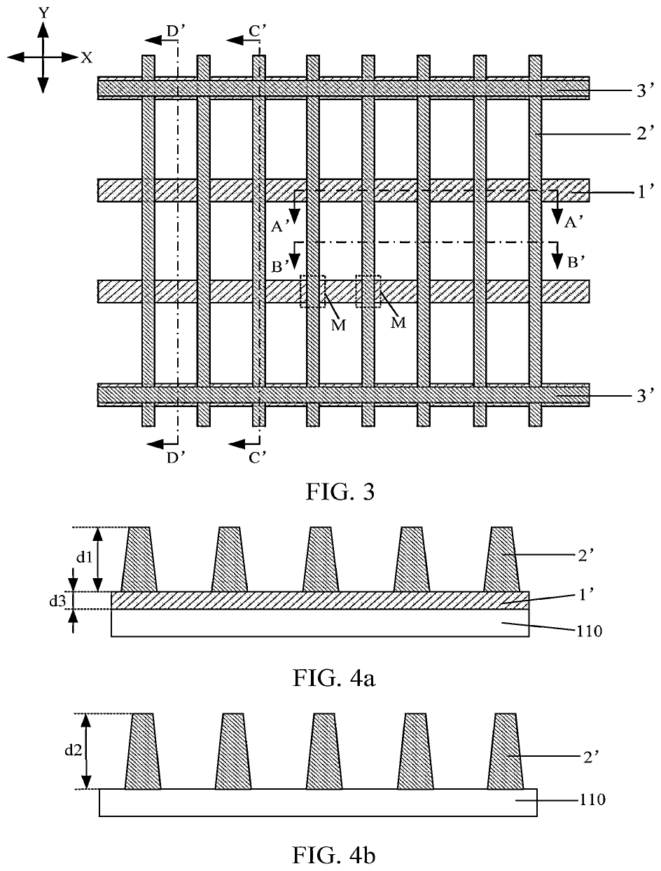

As shown in FIG. 3, FIG. 3 is a schematic diagram of a planar structure of a pixel definition layer of a display substrate in some arts. The pixel definition layer of FIG. 3 has a double-layer Line Bank structure, and the pixel definition layer includes a first pixel definition layer and a second pixel definition layer disposed at a side of the first pixel definition layer away from the base substrate. The first pixel definition layer includes multiple first extension portions 1′ extending along the first direction X, and the multiple first extension portions 1′ are arranged at intervals along the second direction Y. The second pixel definition layer includes multiple second extension portions 2′ extending along the second direction Y, and the multiple second extension portions 2′ are arranged at intervals along the first direction X. The multiple first extension portions 1′ and the multiple second extension portions 2′ intersect with each other to form the multiple pixel openings. Circumferential edges of the pixel definition layer may be located in the non-display area, the second pixel definition layer may further include multiple third extension portions 3′ located in the non-display area extending in the first direction X, and the third extension portions 3′ are stacked at a side of the first extension portions 1′ away from the base substrate, and two third extension portions 3′ and two second extension portions 2′ in the non-display area form the circumferential edges of the pixel definition layer. A material of the first extension portion 1′ is a lyophilic material, and materials of the second extension portions 2′ and the third extension portions 3′ can be the same and be a lyophobic material.

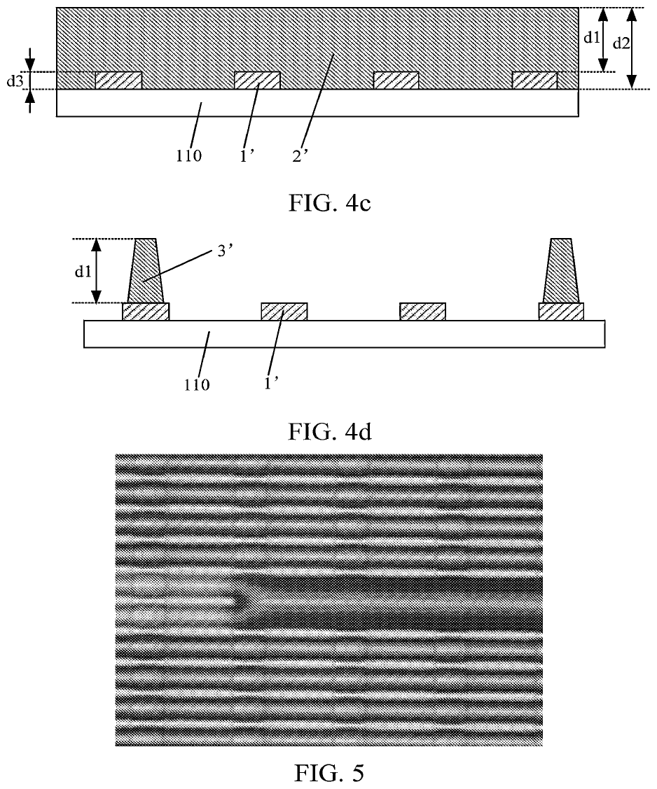

As shown in FIGS. 4a, 4b, 4c and 4d, FIG. 4a is a schematic diagram of a cross-sectional structure taken along A′-A′ in FIG. 3, FIG. 4b is a schematic diagram of a cross-sectional structure taken along B′-B′ in FIG. 3, FIG. 4c is a schematic diagram of a cross-sectional structure taken along C′-C′ in FIG. 3, FIG. 4b is a schematic diagram of a cross-sectional structure taken along D′-D′ in FIG. 3. In the pixel definition layer, a thickness of a portion of a second extension portion 2′ overlapped with a first extension portion 1′ is d1, a thickness of a portion of a second extension portion 2′ located between two adjacent first extension portions 1′ (i.e. a portion of the second extension portion 2′ that is not overlapped with the first extension portions 1′) is d2, a thickness of a first extension portion l′ is d3, and a thickness of a third extension portion 3′ is equal to d1, where d1<d2, d1+d3 is approximately equal to d2.

In some technologies, when the pixel definition layer structure of the example of FIG. 3 is used, and the light emitting functional layer of the OLED light emitting device is formed by using an ink-jet printing process, the ink droplets are readily overflowed at overlapping positions between the first extension portions 1′ and the second extension portions 2′ (in the dashed line frames shown at M in FIG. 3, the overflow occurs at short edge boundaries of adjacent sub-pixels in this example), which causes cross-color of adjacent sub-pixels in the first direction X, which affects the display effect. As shown in FIG. 5, FIG. 5 is a schematic diagram of a structure in which an overflow occurs in a process of forming an organic film layer of an OLED device using an ink-jet printing process using the pixel definition layer structure of FIG. 3. The inventor of the present application analyzed that a main cause of the overflow problem is: on the one hand, a thickness d1 of a portion of the lyophobic second extension portion 2′ overlapped with the first extension portion 1′ is smaller than a thickness d2 of the portion of the second extension portion 2′ located between two adjacent first extension portions 1′, i.e. the portion of the lyophobic second extension portion 2′ that is overlapped with the first extension portions 1′ is relatively thin, the lyophobic capacity of the portion of the lyophobic second extension portion 2′ overlapped with the first extension portions 1′ is relatively low, and on the other hand, presence of the first extension portion 1′ between two adjacent second extension portions 2′ results in a reduction in a volume ink droplets accommodated.

An embodiment of the present disclosure provides a display substrate, including a display area and a non-display area located at a periphery of the display area, wherein the display area includes a drive structure layer, a light emitting structure layer and an encapsulation structure layer which are sequentially stacked on the base substrate. The light emitting structure layer includes a first electrode layer, a pixel definition layer, a light emitting functional layer and a second electrode layer.

The first electrode layer includes multiple first electrodes disposed at a side of the drive structure layer away from the base substrate;

The pixel definition layer includes multiple blocking portions extending along a second direction, and the multiple blocking portions are arranged at intervals in a first direction. The pixel definition layer further includes multiple groups of spacing portions, and each group of spacing portions includes multiple spacing portions arranged at intervals along the first direction. Each of the spacing portions is located between two adjacent blocking portions, and the multiple groups of spacing portions are arranged at intervals in the second direction, wherein the first direction intersects with the second direction. The multiple blocking portions and the multiple groups of spacing portions form multiple pixel openings that expose surfaces of the first electrodes away from the base substrate.

A portion of each blocking portion located between two adjacent spacing portions in the first direction is a first portion, and a portion of the blocking portion located between two adjacent first portions in the second direction is a second portion.

In the display area, the first portion includes a first material layer and a second material layer that are sequentially stacked along a direction away from the base substrate, a material of the first material layer is the same as a material of the spacing portions, and the material of the second material layer is the same as a material of the second portion. A thickness of a portion of the second material layer in the first portion that is not overlapped with a first electrode is H1, and a thickness of a portion of the second portion that is not overlapped with the first electrode is H2, H1=H2. Alternatively, in the display area, the material of the first portion is the same as that of the second portion, and the material of the second portion is different from that of the spacing portions, a thickness of a portion of the first portion that is not overlapped with the first electrode is H1, and a thickness of a portion of the second portion that is not overlapped with the first electrode is H2, H1=H2.

The light emitting functional layer is disposed on a surface of the first electrode away from the base substrate, and the second electrode layer is disposed at a side of the pixel definition layer and the light emitting functional layer away from the base substrate. The first electrode, the light emitting functional layer and the second electrode layer are sequentially stacked to form a light emitting device.

For the display substrate according to the embodiment of the present disclosure, in one scheme, in the display area, the second material layer in the first portion is the same material as the second portion, and the portion of the second material layer of the first portion that is not overlapped with the first electrode has a thickness H1, the portion of the second portion that is not overlapped with the first electrode has a thickness H2, H1=H2. Therefore, in some embodiments, a thickness difference between the second material layer in the first portion and the second portion is relatively small, and difference in the lyophobic capacity between them is relatively small. When the light emitting functional layer of the light emitting device is formed by an ink-jet printing process, ink droplets are not easy to overflow at the first portion, thereby reducing the problem of cross-color between adjacent sub-pixels in the first direction caused by the overflow of ink droplets. In another scheme, in the display area, the material of the first portion is the same as the material of the second portion, the portion of the first portion that is not overlapped with the first electrode has a thickness H1, the portion of the second portion that is not overlapped with the first electrode has a thickness H2, H1=H2. Therefore, in some embodiments, a thickness difference between the first portion and the second portion is relatively small, and difference in the lyophobic capacity between them is relatively small. When the light emitting functional layer of the light emitting device is formed by an ink-jet printing process, ink droplets are not easy to overflow at the first portion, thereby reducing the problem of cross-color between adjacent sub-pixels in the first direction caused by the overflow of ink droplets.

In the present disclosure, a thickness of “A” is equal to a thickness of “B” means that a thickness difference between “A” and “B” is allowed within a certain range of error, that is, a ratio between the thickness of “A” and the thickness of “B” ranges from 95% to 105%, which can be considered as the thickness of “A” being equal to the thickness of “B”.

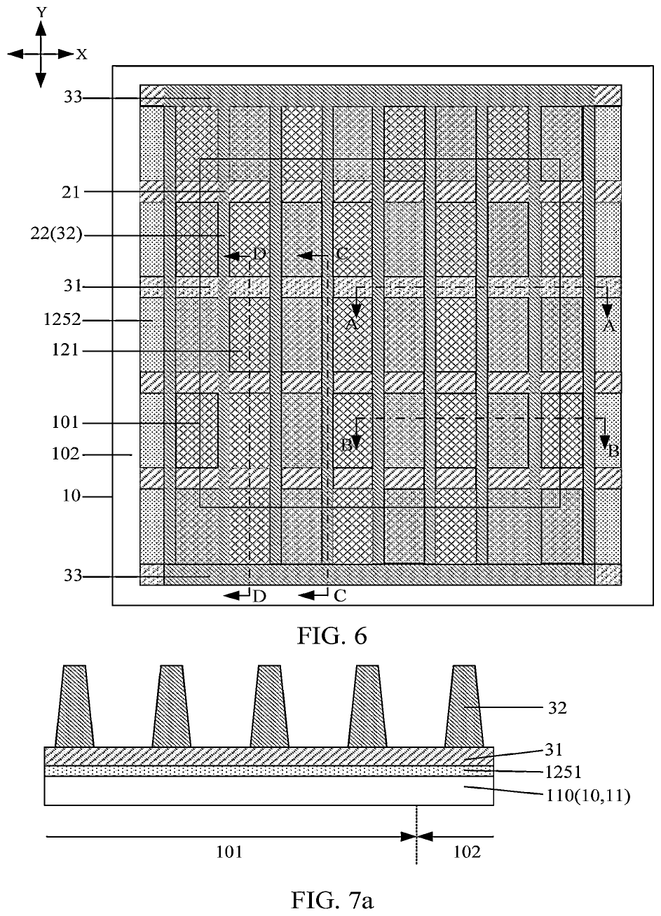

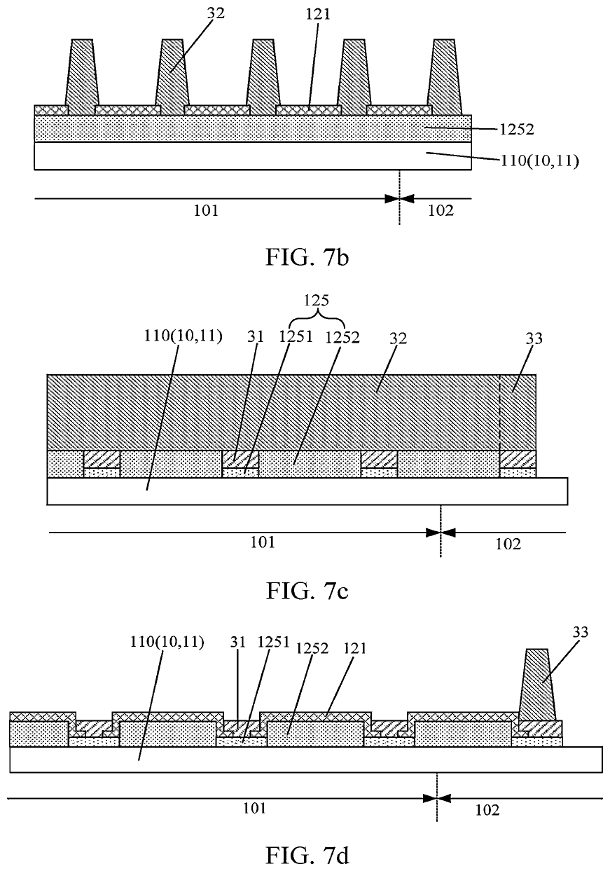

In some exemplary embodiments, as shown in FIGS. 6, 7a, 7b, 7c and 7d, FIG. 6 is a schematic diagram of a planar structure of a display substrate according to some exemplary embodiments, FIG. 7a is a schematic diagram of a cross-sectional structure taken along A-A in FIG. 6 according to some exemplary embodiments, FIG. 7b is a schematic diagram of a cross-sectional structure taken along B-B in FIG. 6 according to some exemplary embodiments, FIG. 7c is a schematic diagram of a cross-sectional structure taken along C-C in FIG. 6 according to some exemplary embodiments, FIG. 7d is a schematic diagram of a cross-sectional structure taken along D-D in FIG. 6 according to some exemplary embodiments. The display substrate includes a display area 101 and a non-display area 102 located at a periphery of the display area 101, wherein the display area 101 includes a drive structure layer, a light emitting structure layer and an encapsulation structure layer which are sequentially stacked on the base substrate 10. The light emitting structure layer includes an adjustment layer, a first electrode layer, a pixel definition layer, a light emitting functional layer and a second electrode layer.

The adjustment layer 125 is disposed at a side of the drive structure layer away from the base substrate 10, the adjustment layer 125 includes multiple first adjustment areas 1251 extending along the first direction X and multiple second adjustment areas 1252 extending along the first direction X, and the first adjustment areas 1251 and the second adjustment areas 1252 are alternately arranged in the second direction Y. A thickness of the first adjustment areas 1251 is smaller than a thickness of the second adjustment areas 1252.

The multiple first electrodes 121 are disposed at a side of the multiple second adjustment areas 1252 away from the base substrate 10.

The pixel definition layer includes a first pixel definition layer and a second pixel definition layer arranged at a side of the first pixel definition layer away from the base substrate 10. The first pixel definition layer includes multiple first extension portions 31 extending along the first direction X, and the first extension portions 31 are disposed at a side of the first adjustment areas 1251 away from the base substrate 10. The second pixel definition layer includes multiple second extension portions 32 extending in the second direction Y, and the second extension portions are disposed at a side of the multiple first extension portions 31 and the multiple second adjustment areas 1252 away from the base substrate 10. The multiple first extension portions 31 and the multiple second extension portions 32 intersect with each other to form multiple pixel openings. An overlapped portion between a second extension portion 32 and a first extension portion 31 form a first portion 21, and a portion of a second extension portion 32 between two adjacent first extension portions 31 (which is not overlapped with the first extension portions 31) forms a second portion 22.

In the display area 101, a thickness of a portion of a second extension portion 32 in the first portion 21 that is overlapped with both a first extension portion 31 and a first adjustment area 1251 and is not overlapped with the first electrodes 121 is H1, and a thickness of a portion of a second extension portion 32 in the second portion 22 that is overlapped with a second adjustment area 1252 and is not overlapped with the first electrodes 121 is H2. A thickness of the first extension portion 31 is H3, a thickness of the first adjustment area 1251 is H4, and a thickness of the second adjustment area 1252 is H5, where H1=H2 and H3+H4=H5.

In this embodiment, the adjustment layer 125 is disposed at the side of the drive structure layer away from the base substrate 10, and the adjustment layer 125 is provided with a first adjustment area 1251 and a second adjustment area 1252 with different thicknesses, the first extension portion 31 is disposed at a side of the first adjustment area 1251 away from the base substrate 10 where a thickness is smaller, and the sum of the thickness H3 of the first extension portion 31 and the thickness H4 of the first adjustment area 1251 is approximately equal to the thickness H5 of the second adjustment area 1252, e.g. H3+H4=H5. Thus, after the first extension portion 31 is formed and before the second extension portion 32 is formed, a surface of the first extension portion 31 is substantially flush with a surface of the second adjustment area 1252, so that a surface around the first electrode 121 is relatively flat. Subsequently, the second extension portion 32 may be formed on a relatively flat surface, so that, the thickness H1 of the portion of the second extension portion 32 that is overlapped with both the first extension portion 31 and the first adjustment area 1251 and is not overlapped with the first electrode 121 is equal to the thickness H2 of the portion of the second extension portion 32 that is overlapped with the second adjustment area 1252 and is not overlapped with the first electrode 121. Thereby, it is possible to reduce a thickness difference between a portion of the second extension portion 32 that is overlapped with the first extension portion 31 (which is a short edge boundary between adjacent sub-pixels in this example) and the portion of the second extension portion 32 that is located between two adjacent first extension portions 31 (which is a long edge boundary between adjacent sub-pixels in this example), thus reducing the difference in the lyophobic capability of the second extension portion 32 at that position, thereby reducing the overflow of ink droplets at the short edge boundaries of adjacent sub-pixels when the light-emitting functional layer 123 is formed by an ink-jet printing process. In addition, since H3+H4=H5, i.e. the surface of the first extension portion 31 is substantially flush with the surface of the second adjustment area 1252, so that the printing ink flowing at the short edge of the sub-pixels can be enhanced, the influence on the ink flow due to the presence of the first extension portion 31 can be reduced, the ink accumulation at the short edge boundary of adjacent sub-pixels can be avoided, and the occurrence of the overflow of ink droplets can be further reduced.

In an example of this embodiment, there may be an overlapped area between an orthographic projection of the first extension portion 31 on the base substrate 10 and an orthographic projection of the first electrode 121 on the base substrate 10, and there may be an overlapped area between an orthographic projection of the second extension portion 32 on the base substrate 10 and an orthographic projection of the first electrode 121 on the base substrate 10.

In the present disclosure, there is an overlapped area between “A” and “B”, or “A” and “B” are overlapped, means that there is an overlapped area between an orthographic projection of “A” on the base substrate and an orthographic projection of “B” on the base substrate.

By way of example, as shown in FIG. 7d, there may be an overlapped area between an orthographic projection of the first electrode 121 on the base substrate 10 and an orthographic projection of the first adjustment area 1251 on the base substrate 10, for example, a partial edge of the first electrode 121 may be located on a surface of the first adjustment area 1251 away from the base substrate 10, and the first extension portion 31 may be located on a surface of the first adjustment area 1251 away from the base substrate 10 and cover the partial edge of the first electrode 121. Alternatively, in other embodiments, there is no overlapped area between the orthographic projection of the first electrode on the base substrate and the orthographic projection of the first adjustment area on the base substrate, there is an overlapped area between an orthographic projection of a portion of the first extension portion located between two adjacent second extension portions on the base substrate and an orthographic projection of the second adjustment areas on the base substrate, in this way, the portion of the first extension portion located between the two adjacent second extension portions can cover a partial edge of the first electrode located on the surface of the second adjustment area.

In an example of this embodiment, as shown in FIGS. 6, 7c and 7d, the adjustment layer 125 and the pixel definition layer may both extend to the non-display area 102, the second pixel definition layer may further include multiple third extension portions 33 located within the non-display area 102 extending along the first direction X, the third extension portions 33 are located at a side of the stacked first adjustment areas 1251 and first extension portions 31 away from the base substrate 10. By way of example, the adjustment layer 125, the first extension portions 31, and the second extension portions 32 all extend to the non-display area 102, and a relationship between film layer structures of the adjustment layer 125, the first extension portions 31, and the second extension portions 32 in the non-display area 102 may be the same as that of the display area 101. A circumferential edge of the pixel definition layer may be located in the non-display area 102 and a shape of the circumferential edge of the pixel definition layer may be substantially rectangular. The number of the first extension portions 31 and the number of the second extension portions 32 of the non-display area 102 may both be two or more.

By way of example, as shown in FIG. 6, two third extension portions 33 and two second extension portions 32 within the non-display area 102 form the circumferential edge of the pixel definition layer, a thickness of portions of the two third extension portions 33 forming the circumferential edge of the pixel definition layer overlapped with both the first adjustment areas 1251 and the first extension portions 31 is equal to H1, and a thickness of the two second extension portions 32 forming the circumferential edge of the pixel definition layer is equal to H1. That is, the thicknesses of the third extension portions 33 and the second extension portions 32 forming the circumferential edge of the pixel definition layer may be substantially equal and may be substantially equal to a thickness of the second extension portions 32 in the display area 101.

In an example of this embodiment, as shown in FIG. 6, a material of the first extension portions 31 is a lyophilic material and a material of the second extension portions 32 is a lyophobic material. Exemplarily, the material of the first extension portions 31 and the material of the second extension portions 32 may both be a single material or a mixture of multiple materials. In this example, the material of the first extension portions 31 is a lyophilic material, so that when the light emitting functional layer 123 is formed by an ink-jet printing process, it facilitates ink droplets to be spread out in a same row of sub-pixels in the second direction Y, so as to improve uniformity of film formation. The material of the second extension portions 32 is a lyophobic material, which facilitates preventing ink droplets from overflowing in the first direction X.

In an example of this embodiment, as shown in FIG. 7a, the thickness of the first extension portion 31 may be less than the thickness of the second extension portions 32. Thus, when the light emitting functional layer 123 is subsequently formed by an ink-jet printing process, it facilitates the ink droplets to be spread out in a same row of sub-pixels in the second direction Y, so as to improve the uniformity of film formation, and to improve an ability of the second extension portions 32 of blocking the overflow of the ink droplets. Exemplarily, the thickness of the first extension portion 31 may be 0.2 microns to 0.7 microns.

In an example of this embodiment, as shown in FIG. 6, a width of the first extension portion 31 in the second direction Y may be greater than a width of the second extension portion 32 in the first direction X. In this way, it is conducive to improving an aperture rate of the display substrate.

Exemplary description is made below for a manufacturing process of a display substrate exemplified in FIG. 6. A “patterning process” mentioned in the present disclosure includes processes such as photoresist coating, mask exposure, development, etching, and photoresist stripping. Deposition may be any one or more of sputtering, evaporation, and chemical vapor deposition. Coating may be any one or more of spray coating and spin coating. Etching may be any one or more of dry etching and wet etching. A “thin film” refers to a layer of a thin film prepared from a material on a base substrate using a process of deposition or coating. If no patterning process is needed for the “thin film” in the whole making process, the “thin film” may also be called a “layer”. If the patterning process is needed for the “thin film” in the whole making process, the thin film is called a “thin film” before the patterning process and called a “layer” after the patterning process. The “layer” after the patterning process includes at least one “pattern”. “A and B are arranged in the same layer” in the present disclosure refers to that A and B are simultaneously formed by a same patterning process. In the present disclosure, “an orthographic projection of A includes an orthographic projection of B” means that the orthographic projection of B falls within a range of the orthographic projection of A, or the orthographic projection of A covers the orthographic projection of B.

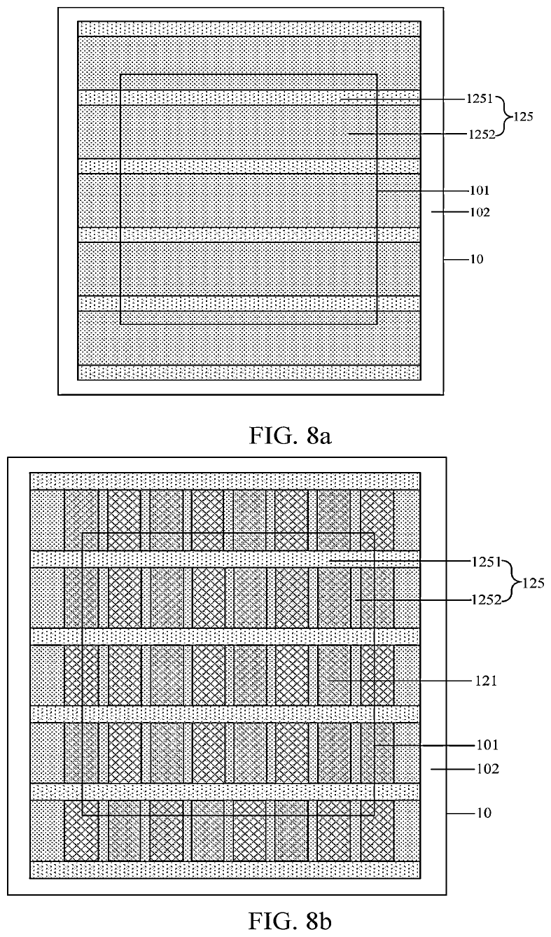

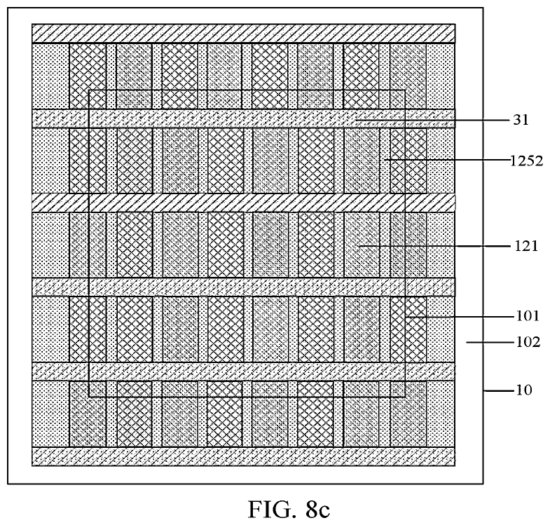

The manufacturing process of the display substrate exemplified in FIG. 6 may include following steps.
(1) Forming a drive structure layer on a base substrate 10. Exemplarily, the base substrate 10 may be a rigid substrate or a flexible substrate, such as a glass substrate. The drive structure layer may include multiple pixel driving circuits. The pixel driving circuit may include multiple thin film transistors (T) and a storage capacitor (C), and the pixel driving circuit may be a structure of 3TIC, 4TIC, 5TIC, 5T2C, 6TIC or 7TIC or the like, which is not limited in the present disclosure. The drive structure layer further includes multiple data lines and multiple gate lines, as well as other signal lines. Forming the drive structure layer on the base substrate 10 may include: forming multiple thin film transistors and a storage capacitor, as well as multiple data lines, multiple gate lines and other signal lines and the like on the base substrate 10, and then forming a planarization layer covering the aforementioned structures.
(2) Forming an adjustment layer 125 on the drive structure layer. Exemplarily, forming the adjustment layer 125 may include: forming an adjustment thin film on the base substrate 10 on which the aforementioned structures are formed and patterning the adjustment thin film by a patterning process to form the adjustment layer 125. The adjustment layer 125 includes multiple first adjustment areas 1251 extending along a first direction X and multiple second adjustment areas 1252 extending along the first direction X, the first adjustment areas 1251 and the second adjustment areas 1252 are alternately arranged in the second direction Y, wherein a thickness of the first adjustment areas 1251 is H4, a thickness of the second adjustment areas 1252 is H5, and H4<H5. Each second adjustment area 1252 may be provided with a first opening which may expose a drain electrode of a thin film transistor (which may be a driving transistor in a pixel driving circuit) in the drive structure layer, so that a subsequently formed first electrode 121 is connected to the drain electrode of the thin film transistor. The adjustment layer 125 is disposed in the display area 101 and can extend to the non-display area 102. The above content may be understood with reference to FIG. 8a.
(3) Forming first electrodes 121 on the adjustment layer 125. Exemplarily, forming the first electrodes 121 may include: depositing a first electrode thin film on the base substrate 10 on which the aforementioned structures are formed, patterning the first electrode thin film by a patterning process to form multiple first electrodes 121 located in the display area 101. The multiple first electrodes 121 are located on surfaces of the multiple second adjustment areas 1252 away from the base substrate 10, and the first electrodes 121 are connected to the drain electrode of the thin film transistors through the first openings. The above contents may be understood with reference to FIG. 8b.
(4) Forming a first pixel definition layer. Exemplarily, forming the first pixel definition layer may include: forming a first pixel definition thin film on the base substrate 10 on which the aforementioned structures are formed (e.g. a coating process may be employed), and patterning the first pixel definition thin film by a patterning process to form the first pixel definition layer. The first pixel definition layer includes multiple first extension portions 31 extending in the first direction X, each of the first extension portions 31 is disposed on a surface of a corresponding first adjustment area 1251 away from the base substrate 10. Two ends of the multiple first extension portions 31 of the display area 101 may extend to the non-display area 102, and more than two first extension portions 31 may be provided in the non-display area 102. The above contents may be understood with reference to FIG. 8c.
(5) Forming a second pixel definition layer. Exemplarily, forming the second pixel definition layer may include: forming a second pixel definition thin film on the base substrate 10 on which the aforementioned structures are formed (e.g. a coating process may be employed), and patterning the second pixel definition thin film by a patterning process to form the second pixel definition layer. The second pixel definition layer includes multiple second extension portions 32 extending in the second direction Y and multiple third extension portions 33 extending in the first direction X. The second extension portions 32 are disposed on surfaces of the multiple first extension portion 31 and the multiple second adjustment areas 1252 away from the base substrate 10, and the multiple first extension portions 31 and the multiple second extension portions 32 intersect with each other to form the multiple pixel openings. The third extension portions 33 are disposed on surfaces of the stacked first adjustment areas 1251 and first extension portions 31 of the non-display area 102 away from the base substrate 10. Two third extension portions 33 and two the second extension portions 32 in the non-display area 102 form a circumferential edge of the pixel definition layer. The above contents may be understood with reference to FIG. 6.
(6) Forming a light emitting functional layer. By way of example, the light emitting functional layer may be disposed within the pixel openings, the light emitting functional layer may include an organic light emitting layer (i.e., a light emitting material layer), and the light emitting functional layer may further include any one or more film layers of a hole injection layer, a hole transport layer, an electron transport layer, and an electron injection layer. Film layers, such as the organic light emitting layer, can be formed by an ink-jet printing process.
(7) Forming a second electrode layer. Exemplarily, the second electrode layer may be formed using an evaporation process or an ink-jet printing process. After the second electrode layer is formed, film layers, such as an encapsulation structure layer, can be formed.

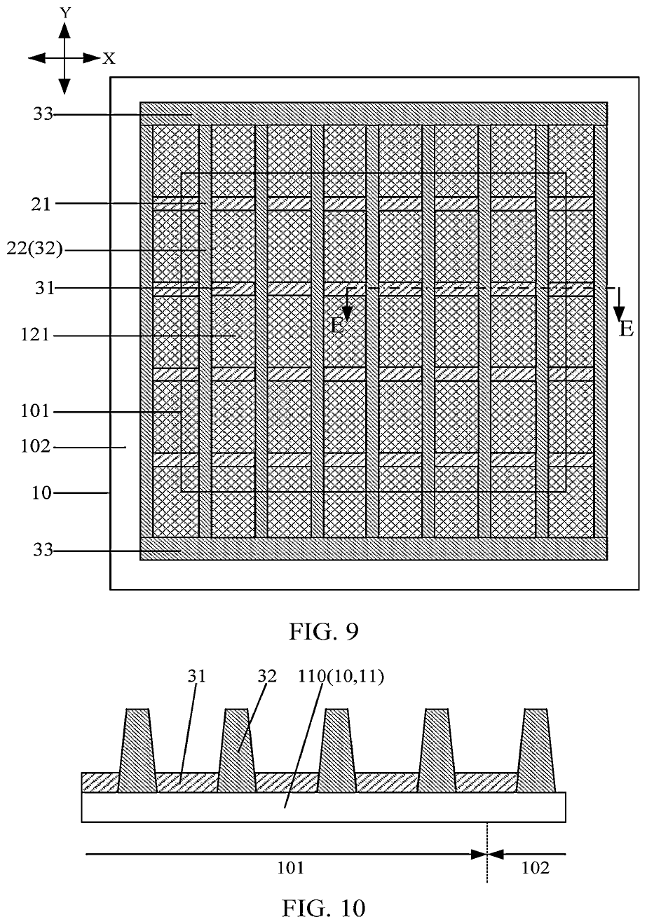

In some other exemplary embodiments, as shown in FIG. 9, FIG. 9 is a schematic diagram of a planar structure of a display substrate according to some other exemplary embodiments, the display substrate includes a display area 101 and a non-display area 102 located at a periphery of the display area 101, the display area 101 includes a drive structure layer, a light emitting structure layer and an encapsulation structure layer that are sequentially stacked on the base substrate 10. The light emitting structure layer includes a first electrode layer, a pixel definition layer, a light emitting functional layer and a second electrode layer.

The first electrode layer includes multiple first electrodes 121 disposed at a side of the drive structure layer away from the base substrate 10.

The pixel definition layer includes a first pixel definition layer and a second pixel definition layer. The second pixel definition layer includes multiple second extension portions 32 extending in the second direction Y, and the multiple second extension portions 32 are arranged at intervals in the first direction X. The first pixel definition layer includes multiple groups of first extension portions 31, and each group of first extension portions 31 includes multiple first extension portions 31 arranged at intervals along the first direction X. Each of the first extension portions 31 is located between two adjacent second extension portions 32, the multiple groups of first extension portions 31 are arranged at intervals in the second direction Y, and the multiple second extension portions 32 and the multiple groups of first extension portions 31 form the multiple pixel openings.

In an example of this embodiment, there may be an overlapped area between a second extension portion and two first extension portions located at two sides of the second extension portion and adjacent in the first direction X, the second extension portion is disposed at a side of the first extension portions away from the base substrate, and a portion of a first extension portion that is not overlapped with the second extension portion is a spacing portion. In this example, a thickness of a portion of the second extension portion that is not overlapped with the first extension portions and is not overlapped with a first electrode may be approximately equal to H1. In another example of this embodiment, as shown in FIG. 9 and FIG. 10, FIG. 10 is a schematic diagram of a cross-sectional structure taken along E-E in FIG. 9 in some exemplary embodiments. There may be no overlapped area between the second extension portion 32 and two first extension portions 31 located at two sides of the second extension portion 32 and adjacent in the first direction X, the first extension portions 31 are spacing portions and the second extension portion 32 is a blocking portion. In this example, there is no overlapped area between the second extension portion 32 and the first extension portions 31, and a thickness of a portion of the second extension portion 32 that is not overlapped with the first electrodes 121 may be approximately equal to H1.

In the two examples of this embodiment, a thickness difference between the portion of the second extension portion 32 located between two adjacent first extension portions 31 in the first direction X (which is a short edge boundary between adjacent sub-pixels in this example) and the portion of the second extension portion 32 located between two adjacent groups of first extension portions 31 (which a long edge boundary between adjacent sub-pixels in this example) can be reduced, thereby reducing the difference in the lyophobic capability of the second extension portion 32 at that position, and reducing the overflow of ink droplets at the short edge boundary between adjacent sub-pixels when the light emitting functional layer 123 is formed by an ink-jet printing process.

In an example of this embodiment, there may be an overlapped area between an orthographic projection of the first extension portions 31 on the base substrate 10 and an orthographic projection of the first electrodes 121 on the base substrate 10, and there may be an overlapped area between an orthographic projection of the second extension portions 32 on the base substrate 10 and the orthographic projection of the first electrodes 121 on the base substrate 10.

In an example of this embodiment, as shown in FIG. 9, a circumferential edge of the pixel definition layer may be located within the non-display area 102, the second pixel definition layer may further include multiple third extension portions 33 extending in the first direction X within the non-display area 102. Two third extension portions 33 and two second extension portions 32 within the non-display area 102 form the circumferential edge of the pixel definition layer. Exemplarily, a shape of the circumferential edge of the pixel definition layer may be substantially rectangular. The number of the second extension portions 32 and the number of the third extension portions 33 of the non-display area 102 may both be two or more. The first extension portions 31 may or may not be disposed at a side of the third extension portions 33 facing the base substrate 10.

By way of an example, a thickness of the two third extension portions 33 forming the circumferential edge of the pixel definition layer is equal to H1, and a thickness of the portions of the two second extension portions 32 which form the circumferential edge of the pixel definition layer and are not overlapped with the first extension portions 31 is equal to H1. That is, thicknesses of the third extension portions 33 and the second extension portions 32 forming the circumferential edges of the pixel definition layer may be substantially equal and may be substantially equal to the thickness of the second extension portions 32 in the display area 101.

In an example of this embodiment, as shown in FIG. 9, a material of the first extension portions 31 is a lyophilic material and a material of the second extension portions 32 is a lyophobic material. Exemplarily, the material of the first extension portions 31 and the material of the second extension portions 32 may both be a single material or a mixture of multiple materials. In this example, the material of the first extension portions 31 is a lyophilic material, so that when the light emitting functional layer 123 is formed by an ink-jet printing process, it facilitates the ink droplets to be spread out in a same row of sub-pixels in the second direction Y, so as to improve the uniformity of film formation. The material of the second extension portions 32 is a lyophobic material, which facilitates preventing ink droplets from overflowing in the first direction X.

In an example of this embodiment, as shown in FIG. 10, the thickness of the first extension portions 31 may be less than the thickness of the second extension portions 32. Thus, when the light emitting functional layer 123 is subsequently formed by an ink-jet printing process, it facilitates the ink droplets to be spread out in the same row of sub-pixels in the second direction Y, so as to improve the uniformity of film formation, and an ability of the second extension portions 32 of blocking the overflow of the ink droplets is improved. Exemplarily, the thickness of the first extension portions 31 may be 0.2 microns to 0.7 microns.

In an example of this embodiment, as shown in FIG. 9, a width of a first extension portion 31 in the second direction Y may be greater than a width of a second extension portion 32 in the first direction X. In this way, it is conducive to improving an aperture rate of the display substrate.

An embodiment of the present disclosure further provides a display device, which includes the display substrate according to any one of the previous embodiments. The display device may be any product or component with a display function, such as a mobile phone, a tablet computer, a television, a display, a laptop computer, a digital photo frame, and a navigator.

In the accompanying drawings, a size of a constituent element, and a thickness of a layer or an area are sometimes exaggerated for clarity. Therefore, an implementation of the present disclosure is not necessarily limited to the size, and the shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus also includes a state in which the angle is above −5° and below 5°. In addition, “vertical” refers to a state in which an angle formed by two straight lines is above 80° and below 100°, and thus also includes a state in which the angle is above 85° and below 95°.

In the specification, a triangle, rectangle, trapezoid, pentagon, hexagon, or the like is not strictly defined, and may be an approximate triangle, rectangle, trapezoid, pentagon, hexagon, or the like, there may be some small deformation caused by tolerance, and there may be chamfers, arc edges, and deformations, etc.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the description herein, unless otherwise specified and defined explicitly, terms “connection”, “fixed connection”, “installation” and “assembly” should be understood in a broad sense, and, for example, may be a fixed connection, a detachable connection or an integrated connection; the terms “installation”, “connection” and “fixed connection” may be a direct connection, an indirect connection through intermediate components, or an internal communication between two components. For those of ordinarily skills in the art, meanings of the above terms in the embodiments of the present disclosure may be understood according to situations.

1. A display substrate, comprising a display area and a non-display area located at a periphery of the display area, wherein the display area comprises a drive structure layer, a light emitting structure layer and an encapsulation structure layer which are sequentially stacked on a base substrate; the light emitting structure layer comprises a first electrode layer, a pixel definition layer, a light emitting functional layer and a second electrode layer;
the first electrode layer comprises a plurality of first electrodes disposed at a side of the drive structure layer away from the base substrate;
the pixel definition layer comprises a plurality of blocking portions extending along a second direction, the plurality of blocking portions are arranged at intervals in a first direction, the pixel definition layer further comprises a plurality of groups of spacing portions, each group of the spacing portions comprises a plurality of spacing portions arranged at intervals along the first direction, each of the spacing portions is located between two adjacent blocking portions, the plurality of groups of spacing portions are arranged at intervals in the second direction, wherein the first direction intersects with the second direction, the plurality of blocking portions and the plurality of groups of spacing portions form a plurality of pixel openings that expose surfaces of the first electrodes away from the base substrate respectively;
a portion of a blocking portion located between two adjacent spacing portions in the first direction is a first portion, and a portion of the blocking portion located between two adjacent first portions in the second direction is a second portion;
in the display area, the first portion comprises a first material layer and a second material layer that are sequentially stacked along a direction away from the base substrate, a material of the first material layer is the same as a material of the spacing portions, a material of the second material layer is the same as a material of the second portion, a thickness of a portion of the second material layer in the first portion that is not overlapped with the first electrodes is H1, and a thickness of a portion of the second portion that is not overlapped with the first electrodes is H2, where H1=H2; or, in the display area, a material of the first portions is the same as a material of the second portion, and the material of the second portion is different from the material of the spacing portions, a thickness of a portion of the first portion that is not overlapped with the first electrodes is H1, and a thickness of a portion of the second portion that is not overlapped with the first electrodes is H2, where H1=H2; and
the light emitting functional layer is disposed on the surfaces of the first electrodes away from the base substrate, and the second electrode layer is disposed at a side of the pixel definition layer and the light emitting functional layer away from the base substrate; a first electrode, the light emitting functional layer and the second electrode layer are sequentially stacked to form a light emitting device.

2. The display substrate according to claim 1, wherein the light emitting structure layer further comprises an adjustment layer disposed at a side of the drive structure layer away from the base substrate, the adjustment layer comprises a plurality of first adjustment areas extending along the first direction and a plurality of second adjustment areas extending along the first direction, the first adjustment areas and the second adjustment areas are alternately arranged in the second direction, and a thickness of the first adjustment areas is smaller than a thickness of the second adjustment areas;
the plurality of first electrodes are disposed at a side of the plurality of second adjustment areas away from the base substrate;
the pixel definition layer comprises a first pixel definition layer and a second pixel definition layer disposed at a side of the first pixel definition layer away from the base substrate;
the first pixel definition layer comprises a plurality of first extension portions extending along the first direction, the first extension portions are disposed at a side of the first adjustment areas away from the base substrate; the second pixel definition layer comprises a plurality of second extension portions extending in the second direction, the second extension portions are disposed at a side of the plurality of first extension portions and the plurality of second adjustment areas away from the base substrate; the plurality of the first extension portions and the plurality of the second extension portions intersect with each other to form the plurality of pixel openings; an overlapped portion between a second extension portion and a first extension portion forms the first portion, and a portion of the second extension portion located between two adjacent first extension portions forms the second portion; and
in the display area, a thickness of a portion of the second extension portion in the first portion that is overlapped with both a first extension portion and a first adjustment area and is not overlapped with the first electrodes is H1, and a thickness of a portion of the second extension portion in the second portion that is overlapped with a second adjustment area and is not overlapped with the first electrodes is H2; a thickness of the first extension portion is H3, a thickness of the first adjustment area is H4, and a thickness of the second adjustment area is H5, where H1−H2 and H3+H4=H5.

3. The display substrate according to claim 2, wherein there is an overlapped area between an orthographic projection of the first extension portion on the base substrate and an orthographic projection of a first electrode on the base substrate, and there is no overlapped area between an orthographic projection of the second extension portion on the base substrate and the orthographic projection of the first electrode on the base substrate.

4. The display substrate according to claim 3, wherein there is an overlapped area between the orthographic projection of the first electrode on the base substrate and an orthographic projection of the first adjustment area on the base substrate; or, there is no overlapped area between the orthographic projection of the first electrode on the base substrate and the orthographic projection of the first adjustment area on the base substrate, and there is an overlapped area between an orthographic projection of a portion of the first extension portion located between two adjacent second extension portions on the base substrate and an orthographic projection of the second adjustment area on the base substrate.

5. The display substrate according to claim 2, wherein the adjustment layer and the pixel definition layer both extend to the non-display area, the second pixel definition layer further comprises a plurality of third extension portions extending in the first direction located in the non-display area, and the third extension portions is located at a side of the stacked first adjustment area and first extension portion away from the base substrate.

6. The display substrate according to claim 5, wherein two third extension portions and two second extension portions in the non-display area form a circumferential edge of the pixel definition layer, a thickness of the two third extension portions forming the circumferential edge of the pixel definition layer that is overlapped with both the first adjustment area and the first extension portion is equal to H1, and a thickness of the two second extension portions forming the circumferential edge of the pixel definition layer is equal to H1.

7. The display substrate according to claim 1, wherein the pixel definition layer comprises a first pixel definition layer and a second pixel definition layer; the second pixel definition layer comprises a plurality of second extension portions extending in the second direction, the plurality of second extension portions are arranged at intervals in the first direction; the first pixel definition layer comprises a plurality of groups of first extension portions, each group of the first extension portions comprises a plurality of first extension portions arranged at intervals along the first direction, each of the first extension portions is located between two adjacent second extension portions, the plurality of groups of first extension portions are arranged at intervals in the second direction, the plurality of second extension portions and the plurality of groups of first extension portions form a plurality of pixel openings;
there is an overlapped area between a second extension portion and two first extension portions located at two sides of the second extension portion and adjacent in the first direction, and the second extension portion is disposed at a side of the first extension portions away from the base substrate, and a portion of a first extension portion that is not overlapped with the second extension portion is a spacing portion; or, there is no overlapped area between the second extension portion and the two first extension portions located at two sides of the second extension portion and adjacent in the first direction, and the first extension portions are the spacing portions and the second extension portion is a blocking portion.

8. The display substrate according to claim 7, wherein there is an overlapped area between an orthographic projection of a first extension portion on the base substrate and an orthographic projection of a first electrode on the base substrate, and there is an overlapped area between an orthographic projection of a second extension portion on the base substrate and the orthographic projection of the first electrode on the base substrate.

9. The display substrate according to claim 7, wherein a circumferential edge of the pixel definition layer are located in the non-display area, the second pixel definition layer further comprises a plurality of third extension portions extending in the first direction located in the non-display area, two third extension portions and two second extension portions in the non-display area form the circumferential edge of the pixel definition layer.

10. The display substrate according to claim 9, wherein a thickness of the two third extension portions forming the circumferential edge of the pixel definition layer is equal to H1, and a thickness of portions of the two second extension portions which form the circumferential edge of the pixel definition layer and are not overlapped with the first extension portions is equal to H1.

11. The display substrate according to claim 2, wherein the first extension portions are made of a lyophilic material and the second extension portions are made of a lyophobic material.

12. The display substrate according to claim 2, wherein a width of a first extension portion is smaller than a width of a second extension portion.

13. The display substrate according to claim 2, wherein a width of a first extension portion in the second direction is greater than a width of a second extension portion in the first direction.

14. The display substrate according to claim 2, wherein the display area comprises a plurality of pixel units arranged in an array on the base substrate, the pixel units comprises a plurality of sub-pixels sequentially arranged in the first direction, and sub-pixels located in a same row in the second direction emit light of a same color.

15. A display apparatus, comprising the display substrate according to claim 1.

16. The display substrate according to claim 3, wherein the first extension portions are made of a lyophilic material and the second extension portions are made of a lyophobic material.

17. The display substrate according to claim 4, wherein the first extension portions are made of a lyophilic material and the second extension portions are made of a lyophobic material.

18. The display substrate according to claim 5, wherein the first extension portions are made of a lyophilic material and the second extension portions are made of a lyophobic material.

19. The display substrate according to claim 6, wherein the first extension portions are made of a lyophilic material and the second extension portions are made of a lyophobic material.

20. The display substrate according to claim 7, wherein the first extension portions are made of a lyophilic material and the second extension portions are made of a lyophobic material.
